(19) United States
(12) Patent Application Publication
(10) Pub. No.: US 2008/0297645 A1
(43) Pub. Date: Dec. 4, 2008

(54) CAMERA MODULE WITH COMPACT PACKAGING OF IMAGE SENSOR CHIP AND METHOD OF MANUFACTURING THE SAME

(75) Inventors: SHIH-MIN LO, Tu-Cheng (TW); AN-CHANG LEI, Tu-Cheng (TW); JEN-CHAO WANG, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Taipei Hsien (TW)

(21) Appl. No.: 11/857,392

(22) Filed: Sep. 18, 2007

(30) Foreign Application Priority Data
May 30, 2007 (CN) 200710200721.7

(51) Int. Cl. H04N 5/225; G03B 17/00; H01L 21/00

(52) U.S. Cl. 348/340; 396/542; 438/69; 257/E21.001; 348/E05.024

(57) ABSTRACT

An exemplary camera module includes a lens holder, a lens module, an image sensor chip, at least three apart bonding pads, and a light transmittance element. The lens module is received in the lens holder. The lens module includes a barrel and at least one lens received in the barrel. The image sensor chip includes a photosensitive area configured for receiving light transmitted through the lens module. The image sensor chip is attached to an end of the lens holder facing away from the lens module. The bonding pads are arranged on the image sensor chip around the photosensitive area. The light transmittance element is fixed on the image sensor chip via the at least three bonding pads. The present invention also relates to a method for manufacturing the camera module.

### TECHNICAL FIELD

The present invention relates to camera modules and, particularly, to a camera module having a compact packaging of image sensor chip and a relatively high image quality, and a method for manufacturing the camera module.

### BACKGROUND

With the ongoing development of micro-circuitry and multimedia technology, digital cameras are now in widespread use. High-end portable electronic devices, such as mobile phones and PDAs (Personal Digital Assistants), are being developed to be increasingly multi-functional. Many of these portable electronic devices are equipped with digital cameras.

A typical digital camera module includes a lens module, a lens holder, and an image sensor chip. The lens holder is a hollow chamber. The lens module is partially received in the lens holder. An IR (infra-red) cut filter is fixed to an inner wall of the lens holder, for protecting the image sensor chip against injury from IR light. The IR cut filter is disposed on the image sensor chip and surrounds a photosensitive area via a continuous adhesive layer.

In the camera module, the adhesive layer is unable to be uniformly distributed on the image sensor chip. Thus, the adhesive layer is prone to having some uneven regions. Accordingly, the IR cut filter, supported on the uneven adhesive layer, is oriented at an oblique angle. When assembling the lens holder to the IR cut filter, the lens holder is slanted at an oblique angle corresponding to the oblique angle of the IR cut filter. As a result, an optical axis of the lens module is misaligned with an optical axis of the image sensor chip. Moreover, the adhesive layer often unduly overflows onto the IR cut filter and spreads to the photosensitive area of the image sensor chip. All of above would impact on image quality of the camera module.

What is needed, therefore, is a camera module that has a relatively high image quality.

What is needed, also, is a method for manufacturing the camera module.

### SUMMARY

In accordance with an embodiment, a camera module includes a lens holder, a lens module, the lens module, an image sensor chip, at least three apart bonding pads, and a light transmittance element. The lens module is received in the lens holder. The lens module includes a barrel and at least one lens received in the barrel. The image sensor chip includes a photosensitive area configured for receiving light transmitted through the lens module. The image sensor chip is attached to an end of the lens holder opposite to the lens module. The image sensor chip includes a photosensitive area configured for receiving light transmitted through the lens module. The bonding pads are arranged on the image sensor chip and surround the photosensitive area. The light transmittance element is fixed on the image sensor chip via the at least three bonding pads.

A method of manufacturing the camera module includes steps as follows. Receiving a lens module to a lens holder, the lens module comprising at least one lens disposed therein. Providing an image sensor chip, the image sensor chip comprising a photosensitive surface and a photosensitive area. Arranging at least three bonding pads on the image sensor chip, the bonding pads being disposed around the photosensitive area. Fixing a light transmittance element on the image sensor chip via the at least three bonding pads, and attaching the image sensor chip to an end of the lens holder opposite to the lens module, thus completing assembly of the camera module.

Other advantages and novel features will be drawn from the following detailed description of at least one present embodiment, when considered in conjunction with the attached drawings.

### BRIEF DESCRIPTION OF THE DRAWINGS

Many aspects of the present camera module and manufacturing method thereof can be better understood with reference to the following drawings. The components in the drawings are not necessarily drawn to scale, the emphasis instead being placed upon clearly illustrating the principles of the present camera module. Moreover, in the drawings, like reference numerals designate corresponding parts throughout the several views.

FIG. 1 is a schematic, cross-sectional view of a camera module including a lens module, a lens holder, an image sensor chip, and a light transmittance element, according to a first present embodiment;

FIG. 2 is a schematic, plan view of the light transmittance element fixed on the image sensor chip of FIG. 1;

FIG. 3 is a flow chart of a method of manufacturing the camera module of FIG. 1;

FIG. 4 is a schematic, cross-sectional view of an alternative camera module, according to a second present embodiment; and

FIG. 5 is a schematic, plan view of a lens holder of the camera module of FIG. 4.

### DETAILED DESCRIPTION OF PREFERRED EMBODIMENTS

Embodiments of the present camera module and manufacturing method thereof will now be described in detail below and with reference to the drawings.

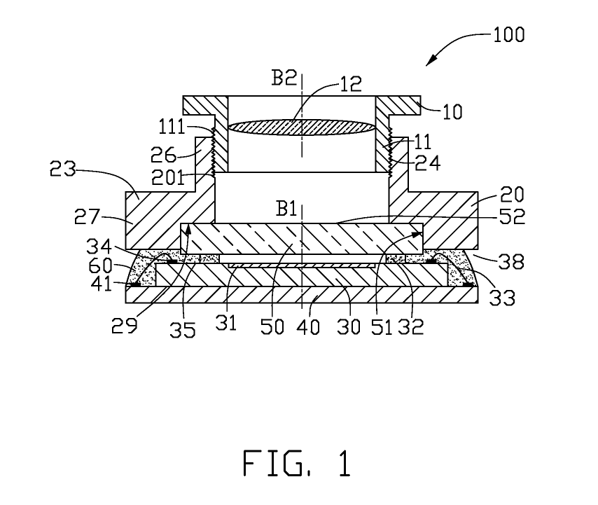

FIG. 1 illustrates a camera module 100, in accordance with a first present embodiment. The camera module 100 includes a lens module 10, a lens holder 20, an image sensor chip 30, and a light transmittance element 50. The lens module 10 is partially received in the lens holder 20. The image sensor chip 30 is fixed to the lens holder 20. The light transmittance element 50 is fixed on the image sensor chip 30.

The lens module 10 includes a barrel 11 and at least one lens 12. The barrel 11 is, advantageously, a hollow cylinder, for receiving the at least one lens 12 therein. The barrel 11 has an external thread 111 formed on an external peripheral surface thereof. In the illustrated embodiment, the at least one lens 12 includes a lens. In other embodiments, the at least one lens 12 could include two or more lenses received in the barrel 11.

The lens holder 20 includes a shoulder portion 23, a front end 26, a rear end 27, and a receiving cavity 21 penetrating/extending through the lens holder 20 from the front end 26 to the rear end 27. The front end 26 and the rear end 27 extend from the shoulder portion 23 along opposing directions of an axis of the lens holder 20. The lens module 10 is received in the lens holder 20 at the front end 26. An internal thread 201 is formed on an internal surface of the front end 26 of the lens holder 20. The barrel 11 is partially received in the lens holder 20 by engaging the external thread 111 of the barrel 11 with the internal thread 201 of the lens holder 20. The shoulder portion 23 of the lens holder 20 has a bottom-most surface 29. The bottom-most surface 29 faces toward the image sensor chip 30.

The image sensor chip 30 is, usefully, disposed on a printed circuit board 40. The image sensor chip 30 has a photosensitive area 31 configured (i.e., structured and arranged) for receiving light transmitted through the lens module 10. A plurality of chip pads 34 is formed on the image sensor chip 30 and disposed around the photosensitive area 31. A plurality of board pads 41 is formed on the printed circuit board 40 and is disposed around the image sensor chip 30. Each chip pad 34 is electrically connected to a corresponding board pad 41, e.g., via a respective wire 33. The wires 33 are, advantageously, made of a conductive material, such as gold, aluminum, or an alloy thereof. A bonding region 35 is defined between the chip pads 34 and the photosensitive area 31.

The rear end 27, the image sensor chip 30, and the printed circuit board 40 cooperatively define a peripheral interspace 38. The wires 33 are received in the interspace 38. An adhesive layer 60 is, advantageously, received in the interspace 38. The adhesive layer 60 is, beneficially, made of a curable adhesive material, for example, a silicone, epoxy, acrylic, or polyamide adhesive. The adhesive layer 60 usefully surrounds the image sensor chip 30, thereby packaging the image sensor chip 30 therein. The rear end 27 could, advantageously, be thicker than the front end 26 of the lens holder 20, in order to provide sufficient adhesion area on the adhesive layer 60. In this circumstance, the lens holder 20 and the printed circuit board 40 are strongly adhered and fixed to each other via the adhesive layer 60.

Quite suitably, The adhesive layer 60 covers the wires 33 and junctions of the wires 33, the chip pads 34, and the board pads 41, in order to protect the wires 33 from metal fatigue, ensure the connections between the ends of the wires 60 and the two pads 34, 41, and to adequately insulate the individual wires 60 to help avoid potential shorting. It is to be understood that the adhesive layer 60 could be applied to the peripheral edge of the interspace 38, apart from the image sensor chip 30, accordingly covering part of each wire 33 and junctions between the ends of the wires 33 and the board pads 41.

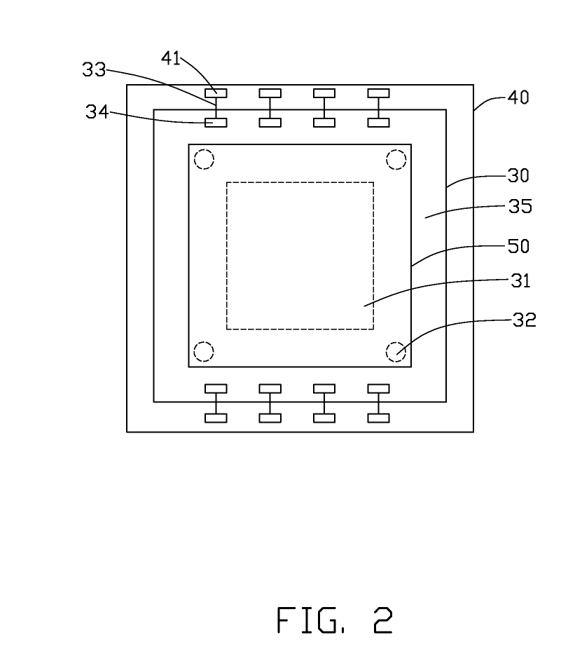

Referring to FIG. 2, the light transmittance element 50 is fixed on the image sensor chip 30 via at least three bonding pads 32 (e.g., bonding beads). Each bonding pad 32 has a small size. In the illustrated embodiment, the light transmittance element 50 is rectangular with four corners and the number of bonding pads 32 is four. The four bonding pads 32 are, beneficially, arranged corresponding to the four corners of the light transmittance element 50. The bonding pads 32 could, advantageously, be made of a bonding material, e.g., curable adhesive or paste. The light transmittance element 50 serves to further protect the image sensor chip 30 and could, e.g., be an IR cut filter or a light transmittance glass.

The light transmittance element 50 is received in the lens holder 20 at the rear end 27. The light transmittance element 50 is, advantageously, attached to the bottom-most surface 29 of the shoulder portion 23. A top surface 52 of the light transmittance element 50 is, beneficially, adhered to the bottom-most surface 29 and lateral surfaces thereof are adhered to an internal circumferential surface 51 of the rear end 27. Alternatively, the light transmittance element 50 is in contact with the bottom-most surface 29 and the internal surface 51 of the rear end 27.

It is to be understood that when utilizing three or more bonding pads, the numerous bonding pads could be uniformly arranged between the bonding region 35 and the light transmittance element 50. Since the numerous bonding pads are apart from each other and have a relatively small volume, heights of the numerous bonding pads can be readily controlled so as to be uniform. Therefore, the light transmittance element 50 is evenly adhered to the bonding region 35 of the image sensor chip 30. Accordingly, when the lens holder 20 is assembled to the light transmittance element 50, an optical axis B1 of the lens module 10 is aligned with an optical axis B2 of the image sensor chip 30. Moreover, the small volume of bonding pads can be readily held at the bonding region 35 and would not overflow to the light transmittance element 50 and the photosensitive area 31. As such, the camera module 100 achieves a desired high image quality.

Otherwise, the lens holder 20 is secured to the image sensor chip 30, not the printed circuit board 40. Therefore, the printed circuit board 40 does not require special space for mounting of the lens holder 20 thereto, thereby reducing size and weight of the camera module 100. Alternatively, the reduced special space of the printed circuit board 40 could be utilized in, e.g., readily and loosely distributing/arraying some required electronic elements (e.g., could thus be possible require less precision in placement of elements, due to greater space availability for such). That potential available space could be used to increase certified product ratio and/or facilitate manufacture of a high quality camera module, thereby decreasing production cost.

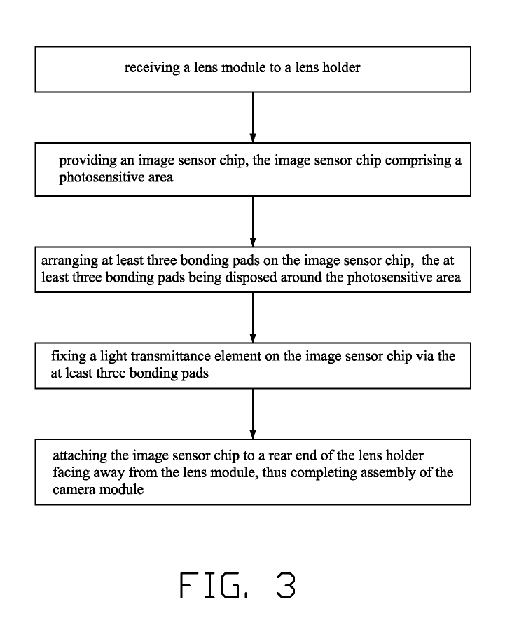

FIG. 3 illustrates a flow chart of a method for manufacturing the camera module 100. The method includes the steps as follows. Receiving a lens module 10 to a lens holder 20. Providing an image sensor chip 30, the image sensor chip 30 including a photosensitive area 31. Arranging at least three bonding pads 32 on the image sensor, the at least three bonding pads 32 being disposed around the photosensitive area 31. Fixing a light transmittance element 50 on the image sensor chip 30 via the at least three bonding pads 32, and attaching the image sensor chip 30 to a rear end 27 of the lens holder 20 facing away from the lens module 10, thus completing assembly of the camera module 100.

Preferably, the method further includes the steps of packaging of the image sensor chip, as follows. Adhering the image sensor chip 30 to a printed circuit board 40. Connecting the chip pads 34 to the board pads 41 via the wires 33, in order to form electrical connection between the image sensor chip 30 and the printed circuit board 40.

The at least three bonding pads 32 could, advantageously, be attached on the image sensor chip 30 via adhesive. The light transmittance element 50 can be fixed on the image sensor chip 30 via the at least three bonding pads 32. The light transmittance element 50 is adhered to the shoulder portion 23 of the lens holder 20 by, e.g., curable adhesive, double-sided adhesive or paste. Moreover, an adhesive layer 60 is advantageously interposed between the rear end 27 of the lens holder 30 and the printed circuit board 40, for packaging the image sensor chip 30 and protecting the wires 33, the chip pads 34, and the board pads 41.

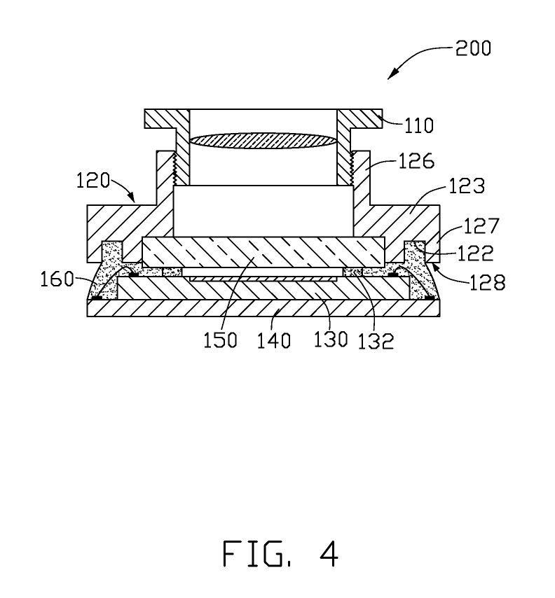

FIG. 4 illustrates another camera module 200, in accordance with a second present embodiment. The camera module 200 includes a lens module 110, a lens holder 120, an image sensor chip 130, a light transmittance element 150, and at least three bonding pads 132. The lens module 110, the image sensor chip 130, the light transmittance element 150, and the bonding pads 132 are similar to the lens module 10, the image sensor chip 30, the light transmittance element 50, and the bonding pads 32, respectively. The lens module 110 is partially received in the lens holder 120. The image sensor chip 130 is fixed to the lens holder 120 and is supported on a printed circuit board 140. The light transmittance element 150 is fixed on the image sensor chip 130 via the bonding pads 132.

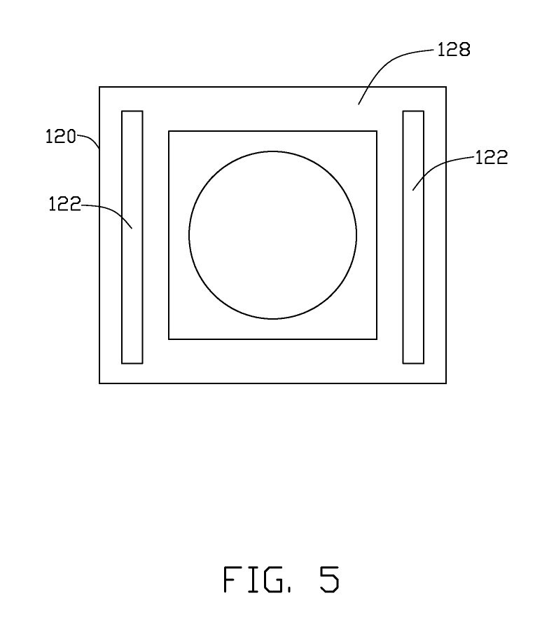

FIG. 5 illustrates the lens holder 120 of the camera module 200. The lens holder 120 is essentially similar to the lens holder 20, except for at least one groove 122 being defined in the lens holder 120. The lens holder 120 includes a shoulder portion 123, a front end 126, and a rear end 127. The at least one groove 122 is defined in a bottom-most face 128 of the rear end 127 and corresponds to the adhesive layer 160. The at least one groove 122 is configured for receiving part of the adhesive layer 160, for improving adhesion strength between the lens holder 120 and the adhesive layer 160.

In the illustrated second embodiment, the rear end 127 of the lens holder 120 is rectangular. There may be two grooves 122 defined in two opposing edge portions of the rear end 127, respectively. Alternatively, the at least one groove 122 could be four elongated grooves 122 defined in four edge portions of the rear end 127, respectively. Alternatively, the four elongated grooves 122 could, e.g., be in communication with each other, thereby forming a circular groove defined in the bottom-most face 128 of the rear end 127.

The manufacturing method of the camera module 200 is essentially similar to the manufacturing method of the camera module 100 in the first present embodiment, except for at least one groove 122 defined in the lens holder 120. The at least one groove 122 could be preformed in bottom-most face 128 of the rear end 127 by, e.g., an etching process or a laser punching process. When applying the adhesive layer 160 between the lens holder 20 and the printed circuit board 40, the adhesive layer 160 spreads into each groove 122. Thus, the volume of the adhesive layer 160 is advantageously sufficient, for example, more than a volume of the adhesive layer 60 in the camera module 100, for partially spreading into the groove 122.

It will be understood that the above particular embodiments and methods are shown and described by way of illustration only. The principles and features of the present invention may be employed in various and numerous embodiments thereof without departing from the scope of the invention as claimed. The above-described embodiments illustrate the scope of the invention but do not restrict the scope of the invention.

What is claimed is:

1. A camera module comprising:
a lens holder;
a lens module received in an end of the lens holder, the lens module comprising a barrel and at least one lens received in the barrel;
an image sensor chip attached to an opposite end of the lens holder away from the lens module, the image sensor chip comprising a photosensitive area configured for receiving light transmitted through the lens module;
at least three apart bonding pads arranged on the image sensor chip around the photosensitive area; and
a light transmittance element disposed between the lens holder and the image sensor chip, the light transmittance element being fixed on the image sensor chip via the at least three bonding pads.

2. The camera module as claimed in claim 1, wherein the lens holder further comprises a shoulder portion formed between said an end and the opposite end.

3. The camera module as claimed in claim 2, wherein an opening is defined in the opposite end of the lens holder, and the light transmittance element is received in the opening and attached to the shoulder portion and an inner wall of the opposite end of the lens holder surrounding the opening.

4. The camera module as claimed in claim 3, wherein the light transmittance element is adhered to the shoulder portion and the inner wall of the lens holder.

5. The camera module as claimed in claim 3, wherein the shoulder portion of the lens holder comprises a bottom-most surface facing towards the image sensor chip and communicating with the opening, the light transmittance element being attached to the bottom-most surface.

6. The camera module as claimed in claim 1, wherein a bonding layer is interposed between the opposite end of the lens holder and the image sensor chip, thereby attaching the image sensor chip to the opposite end of the lens holder.

7. The camera module as claimed in claim 6, wherein the bonding layer surrounds the light transmittance element, the bonding layer and the light transmittance element cooperatively forming a package structure of the image sensor chip.

8. The camera module as claimed in claim 6, wherein the lens holder defines at least one groove at a bottom-most face of the opposite end thereof, part of the bonding layer being received in the at least one groove.

9. The camera module as claimed in claim 8, wherein the at least one groove comprises a circular groove defined along the bottom-most face of the end, the bonding layer comprising a circular projecting portion received in the circular groove.

10. The camera module as claimed in claim 9, wherein the at least one groove comprises two or more grooves uniformly distributed at the bottom-most face of the end.

11. The camera module as claimed in claim 1, wherein the at least three bonding pads are four bonding pads uniformly arranged on the image sensor chip, the four bonding pads being disposed the photosensitive area.

12. The camera module as claimed in claim 1, wherein each bonding pad comprises a bonding material selected from the group consisting of curable adhesive and paste.

13. The camera module as claimed in claim 1, wherein the image sensor chip is supported on a circuit board, the image sensor chip comprising a plurality of chip pads formed around the photosensitive area thereof, the circuit board comprising a plurality of board pads formed thereon, each board pad being electrically connected to a respective chip pad, and wherein the bonding pads are interposed between the chip pads and the photosensitive area.

14. A method of manufacturing the camera module, the method comprising steps of:
receiving a lens module to a lens holder, the lens module comprising a barrel and at least one lens disposed therein;
providing an image sensor chip, the image sensor chip comprising a photosensitive area;
arranging at least three bonding pads on the image sensor chip, the bonding pads being disposed around the photosensitive area;
fixing a light transmittance element on the image sensor chip via the at least three bonding pads; and
attaching the image sensor chip to an end of the lens holder opposite to the lens module.

15. The method as claimed in claim 14, further comprising a step of attaching the light transmittance element to the lens holder.

16. The method as claimed in claim 14, further comprising a step of forming at least one groove at a bottom-most face of the end of the lens holder.

17. The method as claimed in claim 16, wherein the image sensor chip is attached to an end of the lens holder via a bonding layer, the bonding layer surrounding the light transmittance element, part of the bonding layer being received in the at least one groove.

18. A camera module comprising:
a circuit board;
an image sensor chip attached to one surface of the circuit board, the image sensor chip comprising a photosensitive area;
a lens holder attached to the surface of the circuit board via an adhesive layer which surrounds the image sensor chip;
a lens module received in an end of the lens holder, the lens module comprising at least one lens aligned with the photosensitive area of the image sensor chip;
at least three apart bonding beads distributed on the image sensor chip around the photosensitive area; and
a light transmittance element disposed between the lens holder and the image sensor chip configured to transmit light transmitted through the lens module to the photosensitive area of the image sensor chip, the light transmittance element being secured on the image sensor chip via the at least three bonding beads.

19. The camera module as claimed in claim 18, wherein a surface of the lens holder facing the circuit board defines at least one groove, and the bonding layer comprises at least one projecting portion received in the at least one groove.
